(19) United States
(12) Patent Application Publication
(10) Pub. No.: US 2007/0037015 A1
(43) Pub. Date: Feb. 15, 2007

(54) Laminated magnetic media using Ta containing magnetic alloy as the upper magnetic layer

(75) Inventors: Mohammad S. Mirzamaani, San Jose, CA (US); Kai Tang, San Jose, CA (US)

Correspondence Address: Darren Gold;Hitachi Global Storage Technologies, Intellectual Property Law, 5600 Cottle Road, NHGB/0142, San Jose, CA, 95193, US

(73) Assignee: Hitachi Global Storage Technologies Netherlands B.V., Amsterdam (NL)

(21) Appl. No.: 11/202,128

(22) Filed: Aug. 10, 2005

(51) Int. Cl. G11B 5/66; C23C 14/00

(52) U.S. Cl. 428/828; 428/829; 428/828.1; 204/192.2

(57) ABSTRACT

A laminated magnetic recording medium comprising two magnetic layers that are substantially decoupled. The upper magnetic layer is preferably a cobalt alloy that includes tantalum. The tantalum in the upper magnetic layer provides the advantage of improving media SNR with good media stability.

### FIELD OF THE INVENTION

The invention relates to magnetic thin film media with laminated magnetic layers and more particularly to magnetic properties and selection of materials used for the plurality of thin films in such media.

### BACKGROUND OF THE INVENTION

A typical prior art head and disk from a magnetic disk drive 10 are illustrated in block form in FIG. 1. In operation the magnetic transducer 20 is supported by the suspension 13 as it flies above the disk 16. The magnetic transducer 20, usually called a “head” or “slider,” is composed of elements that perform the task of writing magnetic transitions (the write head 23) and reading the magnetic transitions (the read head 12). The electrical signals to and from the read and write heads 12, 23 travel along conductive paths (leads) 14 which are attached to or embedded in the suspension 13. The magnetic transducer 20 is positioned over points at varying radial distances from the center of the disk 16 to read and write circular tracks (not shown). The disk 16 is attached to a spindle 18 that is driven by a spindle motor 24 to rotate the disk 16. The disk 16 comprises a substrate 26 on which a plurality of thin films 21 are deposited. The thin films 21 include ferromagnetic material in which the write head 23 records the magnetic transitions in which information is encoded.

The conventional disk 16 includes substrate 26 of glass or AlMg with an electroless coating of Ni₃P that has been highly polished. The thin films on the disk typically include a chromium or chromium alloy underlayer and at least one ferromagnetic layer based on various alloys of cobalt. For example, a commonly used magnetic alloy is CoPtCr. Additional elements such as tantalum and boron are often used in the magnetic alloy. A protective overcoat layer is used to improve wearability and corrosion resistance. Various seed layers, multiple underlayers and laminated magnetic films have all been described in the prior art. The laminated magnetic films have included multiple ferromagnetic layers that are separated by nonmagnetic spacer layers and more recently antiferromagnetic coupling has been proposed. It is known that substantially improved SNR can be achieved by the use of a laminated magnetic layer structure in which two magnetic layers are substantially decoupled. The reduced media noise is believed due to the reduced exchange coupling between the magnetic layers. The use of lamination for noise reduction has been extensively studied to find favorable spacer layer materials which include Cr, CrV, Mo and Ru, and spacer thicknesses from a few angstroms upward that result in the best decoupling of the magnetic layers and the lowest media noise.

Published US patent application 2005/0019609 by Kai Tang (Jan. 27, 2005) describes an embodiment of the invention which includes at least two laminated ferromagnetic layers with differing magnetic anisotropy. The independent magnetic layer farther away from the recording head is selected to have a lower magnetic anisotropy to allow magnetic switching of the multiple magnetic layers to occur at approximately the same head write current even though the recording head field is reduced with increased distance from the head. The improved switching yields improved magnetic recording performance. Laminated magnetic media according to the described invention can have a single peak in the normalized DC erase noise vs. head write current plot indicating that the magnetic transitions in the non-slave magnetic layers are written at the same head write current. As a result the magnetic pulse width (PW₅₀) is reduced, overwrite (OW) is improved and media signal-to-noise ratio (S₀NR) is improved.

Published US patent application 2002/0098390 by H. V. Do, et al. (Jul. 25, 2002) describes a laminated medium for horizontal magnetic recording that includes an antiferromagnetically (AF)-coupled magnetic layer structure and a conventional single magnetic layer. The AF-coupled magnetic layer structure has a net remanent magnetization-thickness product (Mᵣt) which is the difference in the Mᵣt values of its two ferromagnetic films. The type of ferromagnetic material and the thickness values of the ferromagnetic films are chosen so that the net moment in zero applied field will be low, but nonzero. The Mᵣt for the media is given by the sum of the Mᵣt of the upper magnetic layer and the Mᵣt of the AF-coupled layer stack.

Published US applications 2003/0148143 by Kanabe, et al. (Aug. 7, 2003) and 2003/0104253 by Osawa, et al. (Jun. 5, 2003) describe various magnetic media. However, they do not disclose the use of a laminated magnetic media where the top two magnetic layers are substantially decoupled from one another.

The convention for alloy composition used in this application gives the atomic percentage (at. %) of an element as a subscript; for example, CoCr₁₀ is 10 atomic percent Cr with balance being Co and CoPt₁₁Cr₂₀B₇ is 11 atomic percent Pt, 20 atomic percent Cr and 7 atomic percent boron with the balance being Co.

### SUMMARY OF THE INVENTION

An embodiment of the invention is a laminated magnetic recording medium comprising two magnetic layers that are substantially decoupled. The upper and lower magnetic layers are separated by a nonmagnetic spacer. The upper magnetic layer (nearest the air-bearing surface) is preferably a cobalt alloy having from 12 to 16 at. % platinum (Pt), from 11 to 20 at. % chromium (Cr), from 6 to 14 at. % boron (B) and from 0.5 to 2 at. % tantalum (Ta). The addition of Ta to the upper magnetic layer provides the advantages of improving media SNR with good thermal stability. The lower magnetic layer can be a cobalt alloy having from 11 to 16 at. % platinum (Pt), from 15 to 25 at. % chromium (Cr), from 3 to 14 at. % boron (B) and from 0 to 2 at. % tantalum (Ta). The lower magnetic layer may also be a dual magnetic layer which is comprised of two magnetic sublayers with different compositions for improved recording properties, such as higher SNR, better OW, narrower PW₅₀, higher resolution and better thermal stability. The laminated structure can be used in an embodiment which has a slave magnetic layer separated from the lower magnetic layer by an AFC spacer.

### BRIEF DESCRIPTION OF THE FIGURES

FIG. 1 is a symbolic illustration of the prior art showing the relationships between the head and associated components in a disk drive.

FIG. 2 is an illustration of a prior art layer structure for a magnetic thin film disk with which the magnetic layer stack of the invention can be used.

FIG. 3A is an illustration of a laminated magnetic layer stack comprising an upper magnetic layer and a lower magnetic layer for a magnetic thin film disk according to the prior art.

FIG. 3B is an illustration of a laminated magnetic layer stack comprising an upper magnetic layer and a lower magnetic layer, and the lower magnetic layer being antiferromagnetically coupled to an AFC slave magnetic layer through an AFC spacer layer according to the prior art.

FIG. 3C is an illustration of a laminated magnetic layer stack comprising an upper magnetic layer and a lower magnetic layer, and the lower magnetic layer being a dual magnetic layer according to the prior art.

FIG. 3D is an illustration of a laminated magnetic layer stack comprising an upper magnetic layer and a lower magnetic layer, and the lower magnetic layer being a dual magnetic layer and the lower magnetic layer being antiferromagnetically coupled to an AFC slave magnetic layer through an AFC spacer layer according to the prior art.

FIG. 4A is an illustration of a laminated magnetic layer stack without tantalum in the upper magnetic layer.

FIG. 4B is an illustration of a laminated magnetic layer stack with tantalum in the upper magnetic layer according to the invention.

FIG. 4C is an illustration of a laminated magnetic layer stack with the lower magnetic layer comprising first and second sublayers and without tantalum in the upper magnetic layer.

FIG. 4D is an illustration of a laminated magnetic layer stack with the lower magnetic layer comprising first and second sublayers and with tantalum in the upper magnetic layer according to the invention.

FIG. 5 is a graph of the S₀NR of magnetic films according to the invention versus a prior art example.

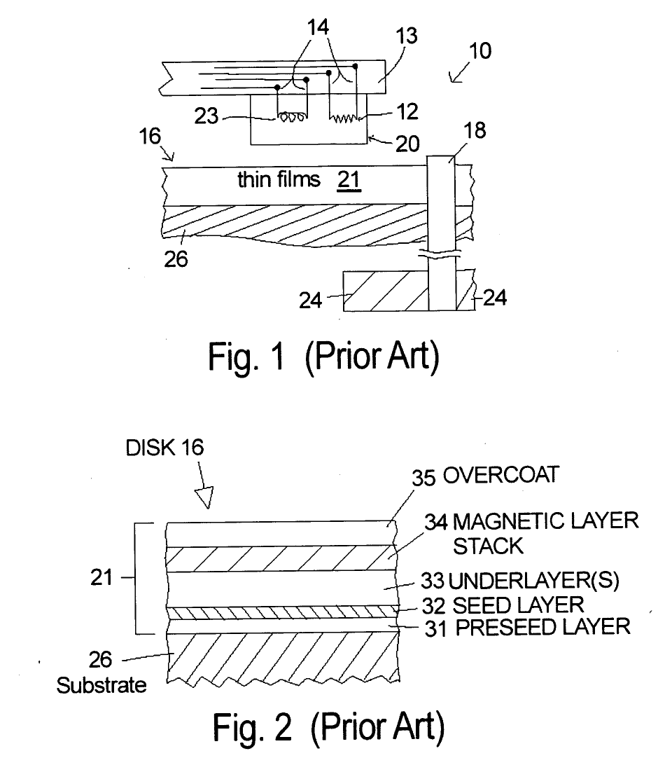

### DETAILED DESCRIPTION OF THE INVENTION AND THE PREFERRED EMBODIMENTS

FIG. 2 illustrates a prior art layer structure 21 of a thin film magnetic disk 16 in which the layer stack according to the invention can be used. The layers under the underlayer(s) 33 may be any of several combinations of seed layers 32 and pre-seed layers 31 as noted in more detail below. Useful pre-seed layers include, but are not limited to, amorphous or nanocrystalline CrTi, CrTiAl or CrTiY. Seed layers are crystalline and are typically used on nonmetallic substrates, but the invention can also be used with metallic substrates such as NiP-coated AlMg. Conventionally NiP-coated AlMg substrates are used with an underlayer structure 33 of Cr, Cr alloy or multiple Cr and Cr alloy layers which are sputter deposited directly onto the NiP. The invention is also not dependent on any particular underlayer being used, but CrTi is used in the preferred embodiment.

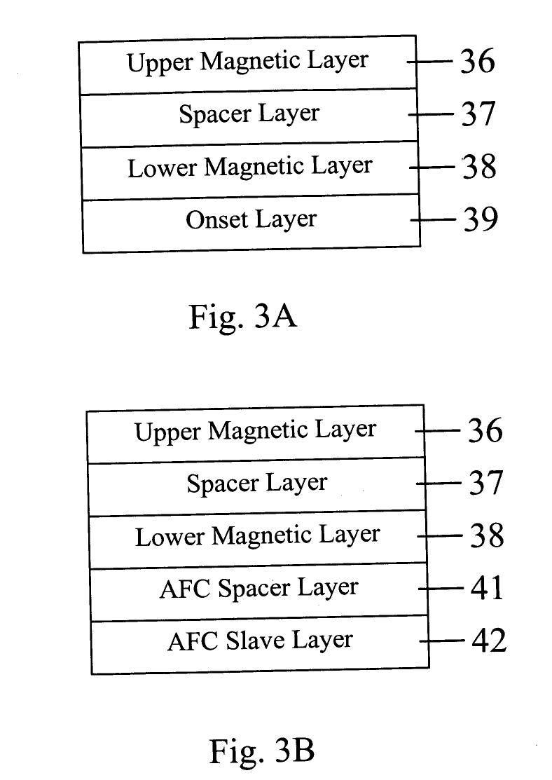

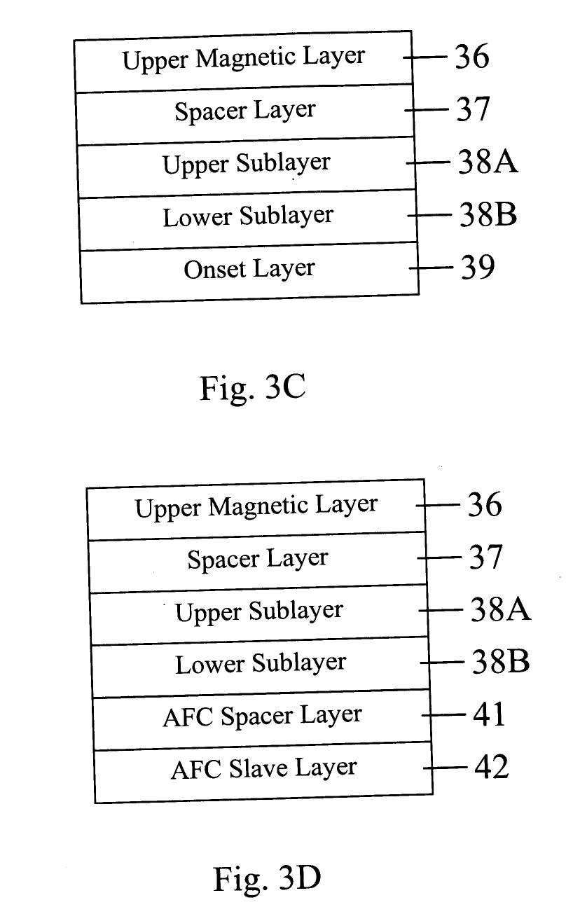

The layer structure shown in FIG. 2 can be used with a variety of magnetic layer stacks 34. For example, a laminated magnetic layer structure can be used as illustrated in FIG. 3A. In this structure there is an upper magnetic layer 36, a spacer layer 37, a lower magnetic layer 38 and an onset layer 39. The spacer layer 37 material and thickness are selected according to the prior art to substantially decouple the upper and lower magnetic layers. The preferred method for determining the thickness of the spacer layer is an empirical one in which tests are performed with varying thicknesses to determine the change in S₀NR. For laminated media the S₀NR will change in a gradual manner in a range of thicknesses before dropping sharply at a certain lower thickness. The spacer thickness is selected to be in the range where high S₀NR is achieved. A typical thickness of the spacer layer is about 8 angstroms. The onset layer 39 which is included in the preferred embodiment is described in the prior art. The onset layer material used with the invention is preferably nonmagnetic or weakly ferromagnetic. A preferred material is CoCr having from 18 to 32 at. % Cr.

FIG. 3B illustrates a second example where a laminated magnetic layer structure is used with an AFC slave magnetic layer 42 separated from the lower magnetic layer 38 by an AFC spacer layer 41. The AFC slave layer 42 which is included in an embodiment is described in the prior art. The AFC slave magnetic layer 42 material used with the invention is preferably ferromagnetic. A preferred material for the AFC slave layer 42 is CoCr having from 6 to 27 at. % Cr. A preferred material for the AFC spacer layer 41 is Ru. In both FIGS. 3A and 3B, the lower magnetic layer can be a dual magnetic layer which is comprised of two magnetic sublayers, illustrated as 38A and 38B in FIGS. 3C and 3D respectively, with different compositions for improved recording properties, such as higher SNR, better OW, narrower PW₅₀, higher resolution and better thermal stability.

Reduction of grain size and decoupling of the grains are helpful for increasing medium signal-to-noise ratio. However, these microstructural changes can degrade medium thermal stability. To alleviate the degradation, Ta is added in the upper magnetic layer 36 in the embodiments illustrated in FIGS. 3A, 3B, 3C and 3D. Ta pushes Cr to the grain boundaries from inside the grains. With such Cr enrichment at the grain boundaries, the grains are well decoupled without significant increase in B content. Increasing B could result in significant increase of thickness of amorphous grain boundaries and refinement of grain size. As a result of adding Ta, medium signal-to-noise ratio can be improved without sacrificing thermal stability.

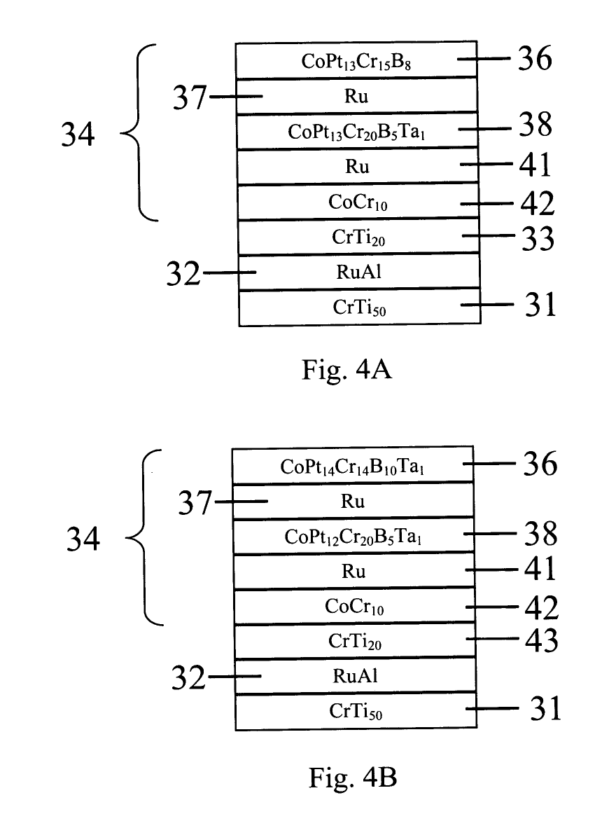

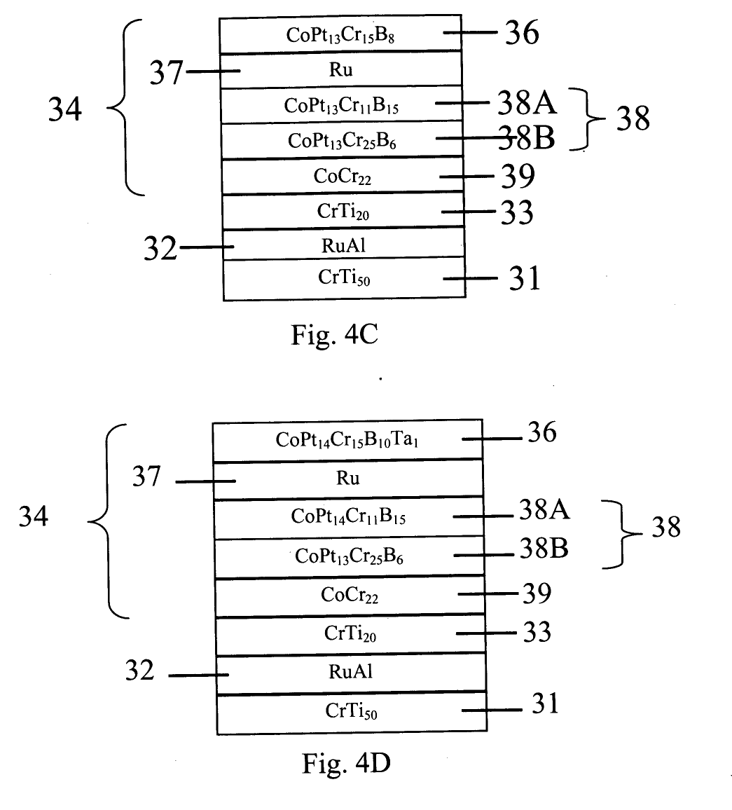

FIG. 4A illustrates a disk, including a laminated magnetic layer stack 34. The magnetic layer nearest to the surface of the disk, the upper magnetic layer 36, is selected according to the prior art for laminated media. In a particular embodiment described below CoPt₁₃Cr₁₅B₈ is used for the upper magnetic layer. The preferred spacer layer 37 is ruthenium. The lower magnetic layer 38 is CoPt₁₃Cr₂₀B₅Ta₁. In the sample embodiment the AFC spacer layer 41 is ruthenium, the AFC slave layer 42 is CoCr₁₀, the underlayer 33 is CrTi₂₀, the seed layer 32 is RuAl₅₀ with a B2 structure and the preseed layer 31 is amorphous or nanocrystalline CrTi₅₀.

FIG. 4B also illustrates a disk, including a laminated magnetic layer stack 34. The magnetic layer nearest to the surface of the disk, the upper magnetic layer 36, is selected to include Ta. In this embodiment CoPt₁₄Cr₁₄B₁₀Ta₁ is used for the upper magnetic layer 36. The preferred spacer layer 37 is ruthenium. The lower magnetic layer 38 is CoPt₁₂Cr₂₀B₅Ta₁. In the sample embodiment the AFC spacer layer 41 is ruthenium, the AFC slave layer 42 is CoCr₁₀, the underlayer 33 is CrTi₂₀, the seed layer 32 is RuAl₅₀ with a B2 structure and the preseed layer 31 is amorphous or nanocrystalline CrTi₅₀.

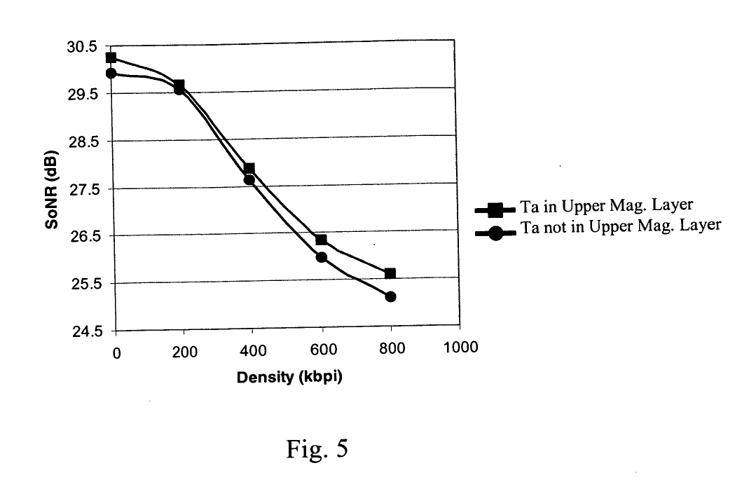

FIG. 5 indicates by using a Ta alloy as upper magnetic layer 36 shown in FIG. 4B, media S₀NR can be improved over the prior art shown in FIG. 4A. Such SNR improvement results in an improved error rate from −5.2 to −5.4 order. Good media thermal stability is also maintained as indicated by an SNR decay rate of 0.92% per decade for a disk with a Ta alloy as the upper magnetic layer versus a 0.97% per decade decay rate for the prior art with a CoPtCrB alloy as the upper magnetic layer.

FIG. 4C illustrates a disk, including a laminated magnetic layer stack 34. The magnetic layer nearest to the surface of the disk, the upper magnetic layer 36, is selected according to the prior art for laminated media. In a particular embodiment described below CoPt₁₃Cr₁₅B₈ is used for the upper magnetic layer 36. The preferred spacer layer 37 is ruthenium. The lower magnetic layer 38 is comprised of upper magnetic sublayer 38A, whose composition is CoPt₁₃Cr₁₁B₁₅, and lower magnetic sublayer 38B, whose composition is CoPt₁₃Cr₂₅B₆. In the sample embodiment the onset layer 39 is CoCr₂₂, the underlayer 33 is CrTi₂₂, the seed layer 32 is RuAl₅₀ with a B2 structure and the preseed layer 31 is amorphous or nanocrystalline CrTi₅₀.

FIG. 4D also illustrates a disk, including a laminated magnetic layer stack 34. The magnetic layer nearest to the surface of the disk, the upper magnetic layer 36, is selected to include Ta. In this embodiment CoPt₁₄Cr₁₅B₁₀Ta₁ is used for the upper magnetic layer. The preferred spacer layer 37 is ruthenium. The lower magnetic layer 38 is comprised of upper magnetic sublayer 38A, whose composition is CoPt₁₄Cr₁₁B₁₅, and lower magnetic sublayer 38B, whose composition is CoPt₁₃Cr₂₅B₆. In the sample embodiment the onset layer 39 is CoCr₂₂, the underlayer 33 is CrTi₂₂, the seed layer 32 is RuAl₅₀ with a B2 structure and the preseed layer 31 is amorphous or nanocrystalline CrTi₅₀.

When using a quinary magnetic alloy (such as CoPt₁₄Cr₁₅B₁₀Ta₁) as the top layer as shown in FIG. 4D, the media exhibits similar SNR and an increased AC squeeze of the medium compared to prior art shown in FIG. 4C, leading to narrowing of MCW (magnetic core width) which allows higher track density and therefore higher areal recording density.

For the invention, the upper layer 36 (nearest the air-bearing surface) is preferably a cobalt alloy having from 12 to 16 at. % platinum (Pt), from 11 to 20 at. % chromium (Cr), from 6 to 14 at. % boron (B) and from 0.5 to 2 at. % tantalum (Ta). One embodiment of the upper magnetic layer 36 is CoPt₁₄Cr₁₄B₁₀Ta₁. A second embodiment of the upper magnetic layer 36 is CoPt₁₄Cr₁₅B₁₀Ta₁.

In a first example, an embodiment of the invention, the lower magnetic layer is preferably a cobalt alloy having from 11 to 16 at. % platinum (Pt), from 15 to 25 at. % chromium (Cr), from 3 to 14 at. % boron (B) and from 0 to 2 at. % tantalum (Ta). One particular embodiment of the lower magnetic layer 38 is CoPt₁₃Cr₂₀B₅Ta₁.

In a second example embodiment of the invention, the lower magnetic layer is comprised of two magnetic sublayers. The upper magnetic sublayer 38A is preferably a cobalt alloy having relatively lower chromium and higher boron content in relation to the lower sublayer. The upper magnetic sublayer is preferably a cobalt alloy having from 9-17 at. % platinum (Pt), 9-15 at. % chromium (Cr), and 11-17 at. % boron (B). Optionally from 1 to 4 at. % of copper can be added to upper sublayer to possibly improve the SNR. The additional copper, if used, will reduce the cobalt content. The preferred thickness of the upper sublayer 38A is from 40-100 angstroms. One embodiment of the upper magnetic sublayer 38A is CoPt₁₄Cr₁₁B₁₅. The lower magnetic sublayer 38B is preferably a cobalt alloy having higher chromium and lower boron content than the upper magnetic sublayer. The lower sublayer is preferably a cobalt alloy having from 9-17 at. % platinum (Pt), 20-28 at. % chromium (Cr), and 4-9 at. % boron (B). Optionally from 1 to 2 at. % of tantalum can be added to the lower sublayer to possibly improve segregation of the grains. The additional tantalum, if used, may reduce the cobalt content. The preferred thickness of the lower sublayer 38B is from 60-110 angstroms. Preferably the ratio of the thickness of the upper sublayer divided by the thickness of the lower sublayer should be from 0.35 to 2.5. One embodiment of the lower magnetic sublayer 38B is CoPt₁₃Cr₂₅B₆.

The compositions of the upper and lower sublayers are selected to have properties that are different from each other and which would make either one not useful if used alone. The different properties of the sublayers combine to provide improved recording performance according to the invention. The upper sublayer composition is selected to have higher coercivity (H_{c}), narrower PW₅₀ and higher resolution. The composition of the lower sublayer is selected for higher SNR, higher thermal stability and better overwrite.

The thin film structures described above can be formed using standard sputtering techniques. The films are sequentially sputter deposited with each film being deposited on the previous film. The upper magnetic layer 36 in the composition ranges given can be deposited with or without using negative substrate bias, ranging from approximately 0 to −300 volts. The upper sublayer 38A and lower sublayers 38B of the lower magnetic layer 38 in the composition ranges given are deposited using negative substrate bias from approximately −100 to −400 volts. The use of bias for these particular composition ranges increases coercivity and AC squeeze of the media, improves the crystallographic structure and grain boundary segregation.

The atomic percentage compositions given above are given without regard for the small amounts of contamination that invariably exist in sputtered thin films as is well known to those skilled in the art.

The invention has been described with respect to particular embodiments, but other uses and applications for the ferromagnetic structure according to the invention will be apparent to those skilled in the art.

What is claimed is:

1. A thin film magnetic recording medium comprising:
an upper magnetic layer nearest to a surface of the thin film magnetic recording medium is an alloy comprising tantalum;
a nonmagnetic spacer layer under the upper magnetic layer;
a lower magnetic layer, under the nonmagnetic spacer layer, which is substantially decoupled from the upper magnetic layer.

2. The recording medium of claim 1 wherein the upper magnetic layer is an alloy including 0.5 to 2.0 atomic percent of tantalum.

3. The recording medium of claim 2 wherein the upper magnetic layer is an alloy including from 12 to 16 atomic percent of platinum, from 11 to 20 atomic percent of chromium, and from 6 to 14 atomic percent of boron.

4. The thin film magnetic recording medium of claim 3 wherein the lower magnetic layer is an alloy including from 11 to 16 atomic percentage of platinum, 15 to 25 atomic percentage of chromium, and 3 to 14 atomic percentage of boron.

5. The recording medium of claim 1 wherein the lower magnetic layer comprises upper and lower sublayers, the upper sublayer being closer to the surface of the thin film magnetic recording medium than the lower sublayer, and the upper sublayer having a different composition than the lower sublayer.

6. The recording medium of claim 5 wherein the upper magnetic layer is an alloy including 0.5 to 2.0 atomic percent of tantalum.

7. The recording medium of claim 5 wherein the upper and lower sublayers being an alloy of cobalt, platinum, chromium, and boron with the upper sublayer having a lower atomic percentage of chromium than the lower sublayer and the upper sublayer having a higher atomic percentage of boron than the lower sublayer.

8. The recording medium of claim 7 wherein the upper sublayer has from 9 to 17 atomic percentage of platinum, 9 to 15 atomic percentage of chromium, and 11 to 17 atomic percentage of boron.

9. The recording medium of claim 7 wherein the lower sublayer has from 9 to 17 atomic percentage of platinum, 20 to 28 atomic percentage of chromium, and 4 to 9 atomic percentage of boron.

10. The recording medium of claim 9 wherein the lower sublayer has from 1 to 2 atomic percent of tantalum.

11. The recording medium of claim 5 wherein a ratio of a thickness of the upper sublayer divided by a thickness of the lower sublayer is from 0.35 to 2.5.

12. The recording medium of claim 1 further comprising an AFC spacer layer under the lower magnetic layer and a slave magnetic layer under the AFC spacer layer, the slave magnetic layer being antiferromagnetically coupled to the lower magnetic layer.

13. The recording medium of claim 1 wherein the lower magnetic layer includes from 0.2 to 2 atomic percent of tantalum.

14. A method of fabricating the recording medium of claim 1 wherein the upper magnetic layer is sputter-deposited using a negative bias from −25 to −300 volts.

15. The method of fabricating the recording medium of claim 14 wherein an upper magnetic sublayer of a lower magnetic layer is sputter-deposited using a negative bias from −100 to −400 volts.

16. The method of fabricating the recording medium of claim 14 wherein a lower magnetic sublayer of a lower magnetic layer is sputter-deposited using a negative bias from −100 to −400 volts.

17. A magnetic disk drive comprising:
a magnetic head for writing magnetic transitions in a magnetic medium on a disk; and
the disk with a magnetic medium comprising:
an upper magnetic layer nearest to a surface of the thin film magnetic recording medium is an alloy comprising tantalum;
a nonmagnetic spacer layer under the upper magnetic layer;
a lower magnetic layer, under the nonmagnetic spacer layer, which is substantially decoupled from the upper magnetic layer and comprised of cobalt, platinum and chromium.

18. The magnetic disk drive of claim 17 wherein the upper magnetic layer is an alloy including 0.5 to 2.0 atomic percent of tantalum.

19. The magnetic disk drive of claim 18 wherein the upper magnetic layer is an alloy including from 12 to 16 atomic percent of platinum, from 11 to 20 atomic percent of chromium and from 6 to 14 atomic percent of boron.

20. The magnetic disk drive of claim 18 wherein the lower magnetic layer has from 11 to 16 atomic percentage of platinum, 15 to 25 atomic percentage of chromium, 3 to 14 atomic percentage of boron and from 0.2 to 2 atomic percent of tantalum.

21. The magnetic disk drive of claim 17 wherein the lower magnetic layer comprises upper and lower sublayers, the upper sublayer being closer to the surface of the thin film magnetic recording medium than the lower sublayer, and the upper magnetic sublayer having an atomic percentage of boron higher than an atomic percentage of boron in the lower magnetic sublayer, the upper magnetic sublayer having an atomic percentage of chromium lower than an atomic percentage of chromium in the lower magnetic sublayer

22. The magnetic disk drive of claim 21 wherein the upper magnetic sublayer has from 9 to 17 atomic percentage of platinum, 9 to 15 atomic percentage chromium, and 11 to 17 atomic percentage of boron.

23. The magnetic disk drive of claim 21 wherein the lower magnetic sublayer has from 9 to 17 atomic percentage of platinum, 20 to 28 atomic percentage of chromium, and 4 to 9 atomic percentage of boron .

24. The magnetic disk drive of claim 23 wherein the lower magnetic sublayer has from 1 to 2 atomic percentage of tantalum.

25. The magnetic disk drive of claim 21 wherein a ratio of a thickness of the upper magnetic sublayer divided by a thickness of the lower magnetic sublayer is from 0.35 to 2.5.
